(19) United States
(12) Patent Application Publication
(10) Pub. No.: US 2024/0329080 A1
(43) Pub. Date: Oct. 3, 2024

(54) SYSTEMS AND METHODS FOR COAXIAL TEST SOCKET AND PRINTED CIRCUIT BOARD INTERFACES

(71) Applicant: Smiths Interconnect Americas, Inc., Kansas City, KS (US)

(72) Inventors: Khaled Elmadbouly, Gilbert, AZ (US); Jiachun Zhou, Fremont, CA (US)

(21) Appl. No.: 18/579,270

(22) PCT Filed: Jul. 12, 2022
(86) PCT No.: PCT/US22/36835

§ 371 Date: Jan. 12, 2024

Related U.S. Application Data
(60) Provisional application No. 63/222,118, filed on Jul. 15, 2021.

(51) Int. Cl. G01R 1/04; G01R 1/067; G01R 3/00

(52) U.S. Cl. CPC G01R 1/0441; G01R 1/06722; G01R 3/00

(57) ABSTRACT

A test socket is provided. The test socket includes a conductive body having a first surface configured to face a printed circuit board (PCB) and a second surface configured to face an integrated circuit (IC) chip. The conductive body defines a signal cavity and a ground cavity that extend from the first surface to the second surface. The test socket further includes a signal probe disposed in the signal cavity. The signal probe is configured to electrically connect to a signal conductor of the PCB and to a signal pad of the IC chip. The test socket further includes a ground probe disposed in the ground cavity. The ground probe is configured to electrically connect to a ground conductor of the PCB and to a ground pad of the IC chip. The conductive body is configured to be electrically connected to the ground conductor of the PCB.

### CROSS-REFERENCE TO RELATED APPLICATIONS

This application is a National Phase entry claiming the benefit of priority under 35 U.S.C. § 371 to International Patent Application No. PCT/US22/36835, filed Jul. 12, 2022, and entitled “SYSTEMS AND METHODS FOR COAXIAL TEST SOCKET AND PRINTED CIRCUIT BOARD INTERFACES,” which claims the benefit of priority to U.S. Provisional Application Ser. No. 63/222,118, filed Jul. 15, 2021, and entitled “SYSTEMS AND METHODS FOR COAXIAL TEST SOCKET AND PRINTED CIRCUIT BOARD INTERFACES,” the contents and disclosures of which are hereby incorporated by reference in their entirety.

### BACKGROUND

The embodiments described herein relate generally to electrical interconnects and, more particularly, to interfaces for coaxial test sockets and printed circuit boards (PCBs).

In the electronics and semiconductor industries, systems used to test integrated circuit (IC) semiconductor chips often include test sockets. A test socket is disposed on a PCB, or “load board,” and may include a socket body and one or more probes (i.e., electrical contacts or pins) that electrically connect the IC chip to the PCB. Test sockets generally must meet various electrical and mechanical performance thresholds to adequately test a given IC chip. For example, the test socket should maintain signal integrity, such as a desired error rate or signal-to-noise ratio, at a desired data transfer rate for the IC under test. Current test sockets generally maintain signal integrity up to a data transfer rate of about 30 gigabits per second. Some applications, such as 5G telecommunications or artificial intelligence, may require higher rates of data transfer. A test socket capable of maintaining signal integrity at higher data transfer rates is therefore desirable.

### BRIEF SUMMARY

In one aspect, a test socket for coupling an integrated circuit (IC) chip to a printed circuit board (PCB) is provided. The test socket includes a conductive body having a first surface configured to face the PCB and a second surface configured to face the IC chip. The conductive body defines a signal cavity and a ground cavity. The signal cavity and the ground cavity extend from the first surface to the second surface. The test socket further includes a signal probe disposed in the signal cavity. The signal probe is configured to electrically connect to a signal conductor of the PCB and to a signal pad of the IC chip. The test socket further includes a ground probe disposed in the ground cavity. The ground probe is configured to electrically connect to a ground conductor of the PCB and to a ground pad of the IC chip. The conductive body is configured to be electrically connected to the ground conductor of the PCB.

In another aspect, a method for manufacturing a test socket is provided. The test socket is configured to couple an integrated circuit (IC) chip to a printed circuit board (PCB). The method includes forming, in a conductive body having a first surface configured to face the PCB and a second surface configured to face the IC chip, a signal cavity and a ground cavity. The signal cavity and the ground cavity extend from the first surface to the second surface. The method further includes positioning a signal probe in the signal cavity. The signal probe is configured to electrically connect to a signal conductor of the PCB and to a signal pad of the IC chip. The method further includes positioning a ground probe in the ground cavity. The ground probe is configured to electrically connect to a ground conductor of the PCB and to a ground pad of the IC chip. The conductive body is configured to be electrically connected to the ground conductor of the PCB.

In another aspect, a test assembly is provided. The test assembly includes an integrated circuit (IC) chip including a signal pad and a ground pad. The test assembly further includes a printed circuit board (PCB) including a signal conductor and a ground conductor. The test assembly further includes a test socket including a conductive body having a first surface configured to face the PCB and a second surface configured to face the IC chip. The conductive body defines a signal cavity and a ground cavity. The signal cavity and the ground cavity extend from the first surface to the second surface. The conductive body is configured to be electrically connected to the ground conductor. The test socket further includes a signal probe disposed in the signal cavity. The signal probe is configured to electrically connect to the signal conductor and to the signal pad. The test socket further includes a ground probe disposed in the ground cavity. The ground probe is configured to electrically connect to the ground conductor and to the ground pad.

### BRIEF DESCRIPTION OF THE DRAWINGS

FIGS. 1-7 show example embodiments of the systems and methods described herein.

FIG. 1 is a cross-sectional view of an example test assembly including an example test socket;

FIG. 2 is a plan view of an example PCB for use in the test assembly shown in FIG. 1;

FIG. 3 is a cross-sectional view of another example test assembly including another example test socket;

FIG. 4 is a plan view of an example PCB for use in the example test assembly shown in FIG. 3;

FIG. 5 is a plan view of another example PCB;

FIG. 6 is a partially transparent plan view of the example PCB shown in FIG. 5; and

FIG. 7 is a flowchart of an example method for manufacturing the test socket shown in FIG. 1.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

Approximating language, as used herein throughout the specification and claims, is applied to modify any quantitative representation that could permissibly vary without resulting in a change in the basic function to which it is related. Accordingly, a value modified by a term or terms, such as “about”, “approximately”, and “substantially”, is not to be limited to the precise value specified. In at least some instances, the approximating language may correspond to the precision of an instrument for measuring the value. Here and throughout the specification and claims, range limitations are combined and interchanged, such ranges are identified and include all the sub-ranges contained therein unless context or language indicates otherwise.

The disclosed systems and methods disclose a test socket for coupling an integrated circuit (IC) chip and a printed circuit board (PCB), for example, to facilitate testing of the IC chip using the PCB. The test socket includes a conductive body having a first surface facing the PCB and a second surface facing the IC chip. The conductive body defines one or more signal cavities and one or more ground cavities, each extending from the first surface to the second surface. The test socket further includes one or more signal probes each disposed in one of the signal cavities. The signal probes are configured to electrically connect to a signal conductor of the PCB and to a signal pad of the IC chip, for example, to enable a transmission of electrical signals between the PCB and the IC chip. The test socket further includes one or more ground probes each disposed in one of the ground cavities. The ground probes are configured to electrically connect to a ground conductor of the PCB and to a ground pad of the IC chip to enable an electrical connection of respective grounds of the PCB and the IC chip. The conductive body may also define one or more power cavities extending from the first surface to the second surface, and in which a power probe may be disposed. Likewise, the power probe is configured to electrically connect to a power conductor of the PCB and to a power pad of the IC chip. The conductive body is configured to be electrically connected to the ground conductor of the PCB, enabling the conductive body to function as a coaxial shielding for the signal probe and enabling the test socket to achieve improved electrical performance on parameters such as, for example, a higher data transfer rate.

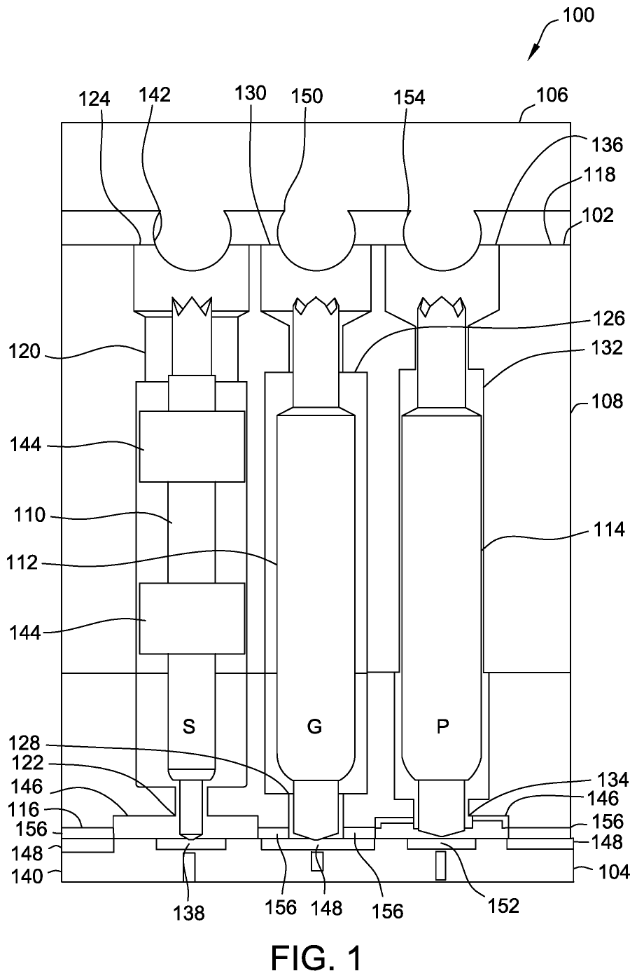

FIG. 1 is a cross-sectional view of a portion of an example test assembly 100 including a test socket 102, a printed circuit board (PCB) 104, and an integrated circuit (IC) chip 106. In some embodiments, test socket 102 is configured to enable a communicative coupling of IC 106 chip to PCB 104 for testing IC chip 106. As described in further detail below, test socket 102 provides for the transmission of electrical signals and electrical power between PCB 104 and IC chip 106 and a connection of respective electrical grounds of PCB 104 and IC chip 106.

Test socket 102 includes a conductive body 108, a signal probe 110, a ground probe 112, and a power probe 114. Conductive body 108 has a first surface 116 disposed adjacent to PCB 104 and a second surface 118 disposed adjacent to IC chip 106. Conductive body 108 is electrically conductive, and includes a conductive material such as, for example, aluminum, magnesium, titanium, zirconium, copper, iron, or an alloy including one or more thereof. Conductive body 108 includes a plurality of cavities, including a signal cavity 120 extending from a first signal opening 122 at first surface 116 to a second signal opening 124 at second surface 118, a ground cavity 126 extending from a first ground opening 128 at first surface 116 to a second ground opening 130 at second surface 118, and a power cavity 132 extending from a first power opening 134 at first surface 116 to a second power opening at 136 at second surface 118. In some embodiments, conductive body 108 includes a plurality of signal cavities 120, ground cavities 126, and/or power cavities 132. In certain embodiments, a distance between any two of signal probe 110, ground probe 112, and power probe 114 is greater than about 50 millimeters center to center.

Signal probe 110 is located within signal cavity 120, and is configured to contact and electrically connect to a signal conductor 138 disposed on a substrate 140 of PCB 104 and to a signal pad 142 of IC chip 106 to enable a transmission of electrical signals between PCB 104 and IC chip 106. Signal probe 110 may include a single conductive piece or may include multiple components. For example, in some embodiments, signal probe 110 is a spring probe. Signal probe 110 is electrically insulated from conductive body 108. For example, in certain embodiments, signal probe 110 or signal cavity 120 may include an electrically insulative coating (not shown). In such embodiments, the insulative coating may be, for example, an anodic film generated on the metal, a polytetrafluoroethylene (PTFE) coating, a combination thereof, or another coating or sealing material. For example, in some such embodiments, the coating includes an anodized aluminum layer having a thickness of greater than about 0.02 millimeters and a PTFE sealing layer having a thickness of greater than about 0.001 millimeters. In some embodiments, signal probe 110 includes one or more insulation members 144 disposed on signal probe 110. While two insulation members 144 are shown, there may be more or less than two insulation members 144 on signal probe 110. Insulation members 144 may be rings that wrap around a portion of a circumference of the outside surface of signal probe 110 or may wrap around the entirety of a circumference of the outside surface of signal probe 110. Accordingly, insulation members 144 may be annular in shape. In some embodiments, insulation members 144 include an insulator material such as, for example, PTFE. In certain embodiments, conductive body 108 includes a recess 146 defined around first signal opening 122 to provide additional electrical isolation between signal probe 110 and the electrical ground. As described in further detail below, a depth of recess 146 may be selected to achieve certain electrical characteristics. In some such embodiments, the depth of recess 146 is in a range from about 0.02 millimeters to about 0.1 millimeters.

Signal probe 110 and signal cavity 120 together form a coaxial transmission line. Accordingly, signal probe 110, signal cavity 120, insulation members 144, and recesses 146 may be shaped and sized to achieve desired electrical properties such as, for example, achieving a constant impedance, reducing reflection or distortion of electrical signals, reducing insertion loss and return loss, achieving a desired characteristic impedance, and/or reducing crosstalk.

Ground probe 112 is located within ground cavity 126, and is configured to contact and electrically connect to a ground conductor 148 of PCB 104 and a ground pad 150 of IC chip 106 to electrically connect respective grounds of PCB 104 and IC chip 106. Like signal probe 110, ground probe 112 may include a single conductive piece or include multiple components. For example, in some embodiments, ground probe 112 is a spring probe. As described in further detail below, conductive body 108 may be electrically connected to ground conductor 148 of PCB 104. Accordingly, unlike signal probe 110, ground probe 112 may be not electrically insulated from conductive body 108.

Power probe 114 is located within power cavity 132, and is configured to contact and electrically connect to a power conductor 152 of PCB 104 and a power pad 154 of IC chip 106 to provide power to IC chip 106 from PCB 104. Like signal probe 110 and ground probe 112, power probe 114 may include a single conductive piece or include multiple components. For example, in some embodiments, power probe 114 is a spring probe. Like signal probe 110, power probe 114 is electrically insulated from conductive body 108. For example, in certain embodiments, power probe 114 may include an electrically insulative coating (not shown) and/or insulation members similar to insulation members 144. In certain embodiments, conductive body 108 includes a recess 146 defined around first power opening 134 to provide additional electrical isolation between power probe 114 and the electrical ground.

Conductive body 108 is electrically connected to ground conductor 148 of PCB 104. In some embodiments, as shown in FIG. 1, a conductive elastomer 156 is disposed between conductive body 108 and ground conductor 148 of PCB 104 to form the electrical connection between conductive body 108 and ground conductor 148. Additionally or alternatively, a conductive foil, such as a gold foil, may be disposed between conductive body 108 and ground conductor 148 to further improve the electrical connection. In certain embodiments, first surface 116 is rough to improve contact between conductive body 108 and ground conductor 148.

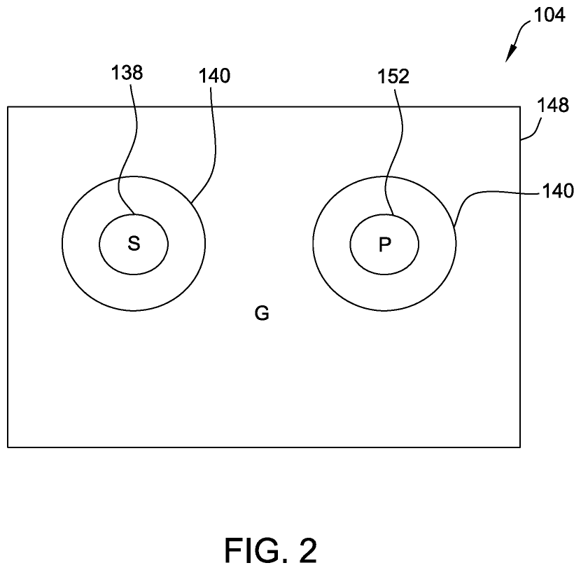

FIG. 2 is a plan view of example PCB 104 as used in test assembly 100. PCB 104 includes signal conductor 138, substrate 140, ground conductor 148, and power conductor 152. Substrate 140 includes one or more insulation materials such as, for example, an FR-4 material or solder mask material. Signal conductor 138, ground conductor 148, and power conductor 152 include conductive layers disposed on substrate 140, vias extending through substrate 140, or a combination thereof. As shown in FIG. 2, in some embodiments, ground conductor 148 includes a ground plane, which as described above, may be electrically connected to conductive body 108 of test socket 102. Signal conductor 138 and power conductor 152 include pads positioned to contact signal probe 110 and power probe 114, respectively. The arrangement of signal conductor 138 and power conductor 152 may be selected based on a design of a particular IC chip 106 that is to be tested using test socket 102. For example, signal conductor 138 and power conductor 152 may be positioned to align with respective signal pads 142 or power pads 154 of IC chip 106. As shown in FIG. 2, in certain embodiments, signal conductor 138 and power conductor 152 include conductive layers that are circular in shape. Alternatively, in some embodiments, signal conductors 138 and power conductors 152 may have another shape. In certain embodiments, signal conductor 138 includes or is coupled to a transmission line, such as a microstrip or coaxial transmission line, for transmitting signals to IC chip 106 via test socket 102.

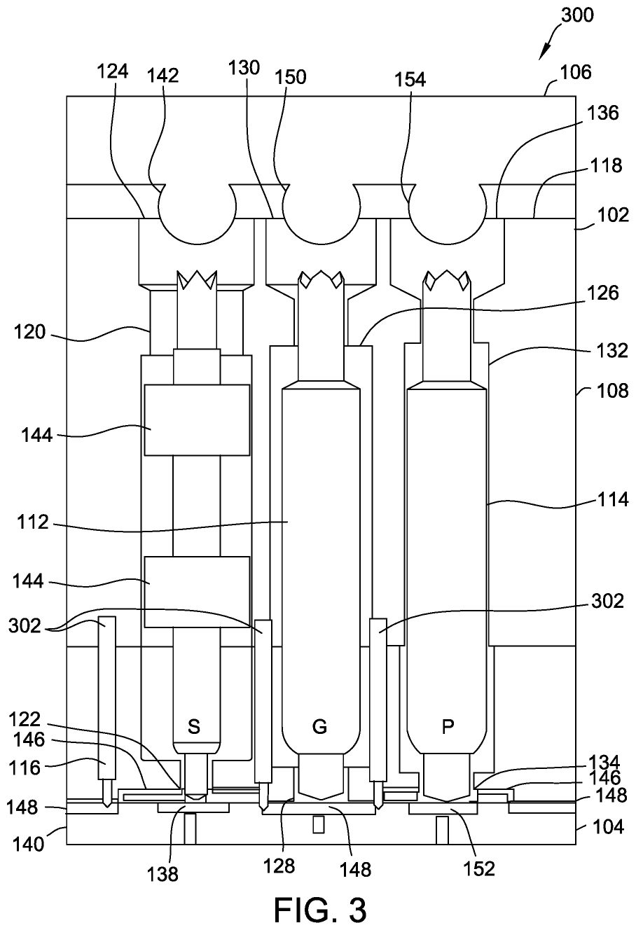

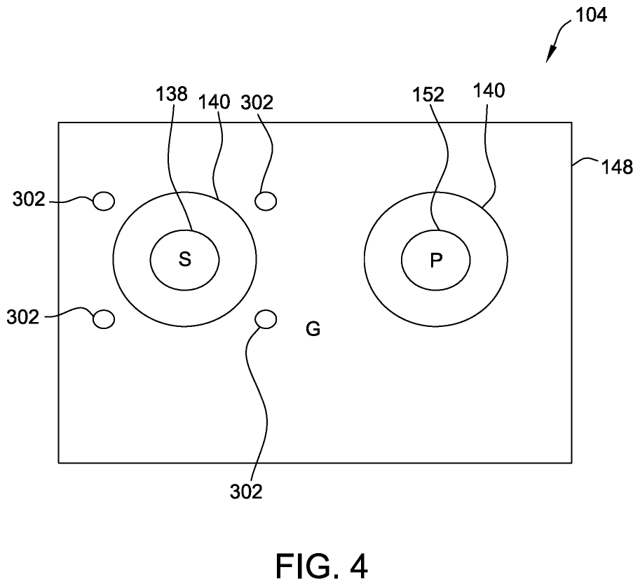

FIG. 3 is a cross-sectional view of an example test assembly 300. Test assembly 300 includes test socket 102, PCB 104, and IC chip 106, which generally function as described with respect to FIG. 1. FIG. 4 is a plan view of PCB 104 as used in test assembly 300. As shown in FIG. 3, in some embodiments, test socket 102 includes one or more shielding probes 302. Shielding probes 302 are partially disposed in and are electrically connected to conductive body 108, and extend from first surface 116. Shielding probes 302 are configured to contact ground conductor 148 to electrically connect conductive body 108 to ground conductor 148. In some embodiments, shielding probes 302 are spring probes. As shown in FIGS. 3 and 4, in certain embodiments, shielding probes 302 are arranged around signal probe 110 and signal cavity 120 and/or ground probe 112 and ground cavity 126. Shielding probes 302 may be used in addition to or as an alternative to other types of coupling conductive body 108 and ground conductor 148, such as positioning conductive body 108 and ground conductor 148 in contact or utilizing conductive elastomer 156 as shown in FIG. 1.

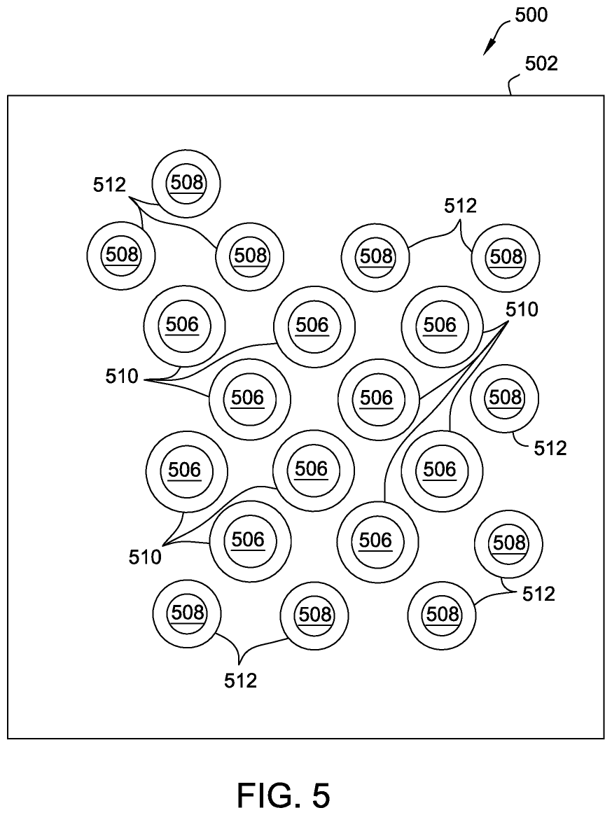

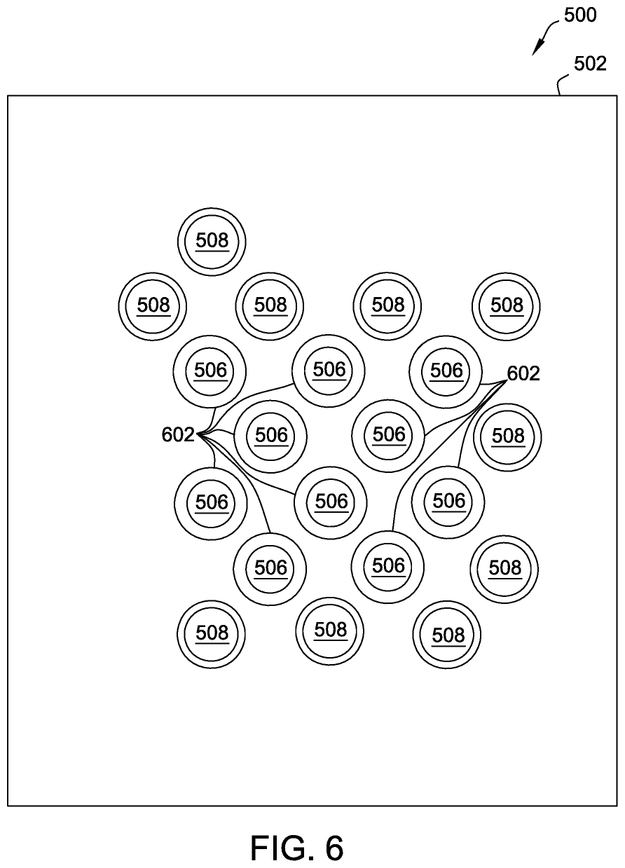

FIG. 5 is a plan view of an example PCB 500, which may be used in a test assembly such as test assembly 100 or test assembly 300. FIG. 6 is a partially transparent view of PCB 500. PCB 500 includes a substrate 502, a ground plane 504, and a plurality of signal pads 506 and ground pads 508. In some embodiments substrate 502 generally functions as described with respect to substrate 140 (shown in FIG. 1). Ground plane 504 is a layer of a conductive material such as, for example, copper, disposed on a surface of substrate 502, and may form at least part of ground conductor 148. In some embodiments, ground plane 504 is about 0.05 millimeters thick. Ground plane 504 includes signal holes 510 and ground holes 512 positioned to expose signal pads 506 and ground pads 508. Signal pads 506 and ground pads 508 are positioned to align with signal probes 110 and ground probes 112, respectively. In certain embodiments, signal holes 510 are about 0.38 millimeters in diameter, and ground holes 512 are greater than about 0.2 millimeters in diameter. As shown in FIG. 6, each signal pad 506 is surrounded by an anti-signal pad region 602 that includes no solder mask.

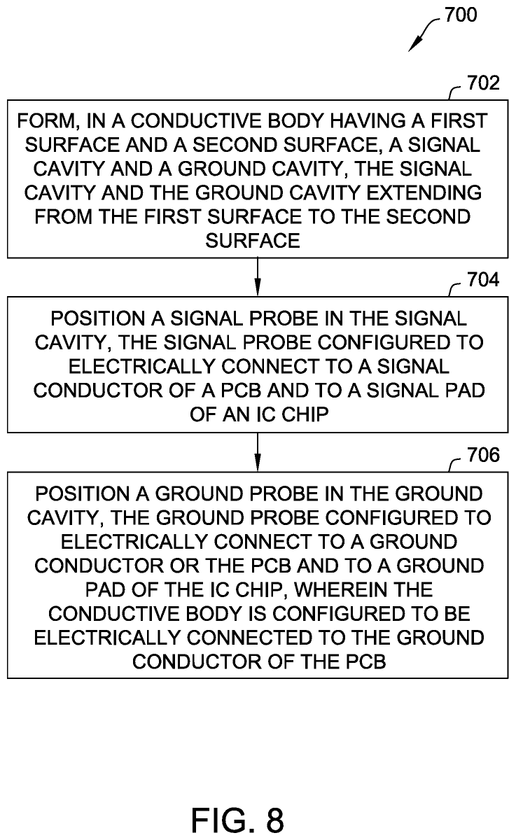

FIG. 7 is a flowchart of an example method 700 for manufacturing test socket 102. Method 700 includes forming 702, in conductive body 108 having a first surface 116 and second surface 118, signal cavity 120 and ground cavity 126. Signal cavity 120 and ground cavity 126 extend from first surface 116 to second surface 118.

Method 700 further includes positioning 704 signal probe 110 in signal cavity 120. Signal probe 110 is configured to electrically connect to signal conductor 138 of PCB 104 and to signal pad 142 of IC chip 106. In some embodiments, at least one of signal probe 110 or conductive body 108 about signal cavity 120 includes an insulative coating. In some such embodiments, the insulative coating includes an anodic film. In certain embodiments, method 700 further includes positioning insulation member 144 on signal probe 110, Insulation member 144 is configured to electrically insulate signal probe 110 from conductive body 108. In some such embodiments, insulation member 144 is annular in shape. In certain such embodiments, insulation members include PTFE or another insulator material.

Method 700 further includes positioning 706 a ground probe 112 in ground cavity 126. Ground probe 112 is configured to electrically connect to ground conductor 148 of PCB 104 and to ground pad 150 of IC chip 106. Conductive body 108 is also configured to be electrically connected to ground conductor 148 of PCB 104. In some embodiments, at least one of signal probe 110 or ground probe 112 is a spring probe.

In some embodiments, method 700 further includes forming, in conductive body 108, a power cavity 132 extending from first surface 116 to second surface 118, and positioning power probe 114 in power cavity 132. Power probe 114 is configured to electrically connect to a power conductor 152 of the PCB and to a power pad of the IC chip. In certain embodiments, power probe 114 is a spring probe. In some embodiments, at least one of power probe 114 or conductive body 108 about power cavity 132 includes an insulative coating.

In some embodiments, method 700 further includes positioning a conductive elastomer 156 adjacent to first surface 116. Conductive elastomer 156 is configured to electrically connect conductive body 108 to ground conductor 148. In certain embodiments, method 700 further includes positioning a gold foil on first surface 116. The gold foil is configured to electrically connect conductive body 108 to ground conductor 148. In some other embodiments, method 700 further includes positioning shielding probe 302 to extend from first surface 116. Shielding probe 302 configured to electrically connect conductive body 108 to ground conductor 148. In some such embodiments, shielding probe 302 is a spring probe.

In certain embodiments, method 700 further includes forming, in conductive body 108, recess 146 extending inward from first surface 116, wherein signal cavity 120 or power cavity 132 opens into recess 146. In some such embodiments, recess 120 has a depth in a range from 0.02 millimeters to 0.1 millimeters.

Example embodiments of methods and systems for coaxial test socket and PCB interfaces are described above in detail. The methods and systems are not limited to the specific embodiments described herein, but rather, components of systems and/or steps of the methods may be used independently and separately from other components and/or steps described herein. Accordingly, the example embodiments can be implemented and used in connection with many other applications not specifically described herein.

Technical effects of the systems and methods described herein include at least one of: (a) improved signal integrity for a coaxial test socket by improving electrical coupling between a conductive body of the test socket and an electrical ground; and (b) increased data transfer rates for a coaxial test socket by improving electrical coupling between a conductive body of the test socket and an electrical ground.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to disclose various embodiments, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claim.

What is claimed is:

1. A test socket for coupling an integrated circuit (IC) chip to a printed circuit board (PCB), said test socket comprising:
a conductive body having a first surface configured to face the PCB and a second surface configured to face the IC chip, said conductive body defining a signal cavity and a ground cavity, the signal cavity and the ground cavity extending from the first surface to the second surface;
a signal probe disposed in the signal cavity, said signal probe configured to electrically connect to a signal conductor of the PCB and to a signal pad of the IC chip; and
a ground probe disposed in the ground cavity, said ground probe configured to electrically connect to a ground conductor of the PCB and to a ground pad of the IC chip, wherein said conductive body is configured to be electrically connected to the ground conductor of the PCB.

2. The test socket of claim 1, wherein said conductive body further defines a power cavity extending from the first surface to the second surface, and wherein said test socket further comprises a power probe disposed in the power cavity, said power probe configured to electrically connect to a power conductor of the PCB and to a power pad of the IC chip.

3. The test socket of claim 2, wherein at least one of said signal probe said ground probe, or said power probe comprises a spring probe.

4. The test socket of claim 2, wherein said conductive body further defines a recess extending inward from the first surface, and wherein at least one of the signal cavity or the power cavity opens into said recess.

5. The test socket of claim 4, wherein the recess has a depth in a range from 0.02 millimeters to 0.1 millimeters.

6. The test socket of claim 2, wherein at least one of said signal probe or said power probe comprises an insulative coating.

7. The test socket of claim 1, further comprising a conductive elastomer disposed adjacent to the first surface and configured to electrically connect said conductive body to the ground conductor of the PCB.

8. The test socket of claim 1, further comprising a gold foil disposed on the first surface and configured to electrically connect said conductive body to the ground conductor of the PCB.

9. The test socket of claim 1, further comprising a shielding probe extending from the first surface and configured to electrically connect said conductive body to the ground conductor of the PCB.

10. The test socket of claim 9, wherein said shielding probe comprises a spring probe.

11. The test socket of claim 1, further comprising an insulation member disposed on said signal probe, said insulation member configured to electrically insulate said signal probe from said conductive body.

12. The test socket of claim 11, wherein said insulation member comprises polytetrafluoroethylene (PTFE).

13. The test socket of claim 11, wherein said insulation member is annular in shape.

14. A method for manufacturing a test socket, the test socket configured to couple an integrated circuit (IC) chip to a printed circuit board (PCB), said method comprising:
forming, in a conductive body having a first surface configured to face the PCB and a second surface configured to face the IC chip, a signal cavity and a ground cavity, the signal cavity and the ground cavity extending from the first surface to the second surface;
positioning a signal probe in the signal cavity, the signal probe configured to electrically connect to a signal conductor of the PCB and to a signal pad of the IC chip; and
positioning a ground probe in the ground cavity, the ground probe configured to electrically connect to a ground conductor of the PCB and to a ground pad of the IC chip, wherein the conductive body is configured to be electrically connected to the ground conductor of the PCB.

15. The method of claim 14, further comprising:
forming, in the conductive body, a power cavity extending from the first surface to the second surface; and
positioning a power probe in the power cavity, the power probe configured to electrically connect to a power conductor of the PCB and to a power pad of the IC chip.

16. The method of claim 15, further comprising forming, in the conductive body, a recess extending inward from the first surface, wherein at least one of the signal cavity or the power cavity opens into the recess.

17. The method of claim 14, further comprising positioning a conductive elastomer adjacent to the first surface, the conductive elastomer configured to electrically connect said conductive body to the ground conductor of the PCB.

18. The method of claim 14, further comprising positioning a shielding probe to extend from the first surface, the shielding probe configured to electrically connect the conductive body to the ground conductor of the PCB.

19. The method of claim 14, further comprising positioning an insulation member on the signal probe, the insulation member configured to electrically insulate the signal probe from the conductive body.

20. An integrated circuit (IC) test assembly comprising:
an IC chip comprising a signal pad and a ground pad;
a printed circuit board (PCB) comprising a signal conductor and a ground conductor; and
a test socket comprising:
a conductive body having a first surface configured to face the PCB and a second surface configured to face the IC chip, said conductive body defining a signal cavity and a ground cavity, the signal cavity and the ground cavity extending from the first surface to the second surface, said conductive body configured to be electrically connected to said ground conductor;
a signal probe disposed in the signal cavity, said signal probe configured to electrically connect to said signal conductor and to said signal pad; and
a ground probe disposed in the ground cavity, said ground probe configured to electrically connect to said ground conductor and to said ground pad
